(19) United States
(12) Patent Application Publication
(10) Pub. No.: US 2026/0343966 A1
(43) Pub. Date: Oct. 29, 2026

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Chun Wei Chen, Hsinchu (TW); Ji-Yin Tsai, Zhudong Township (TW)

(21) Appl. No.: 19/736,123

(22) Filed: Jul. 9, 2026

Related U.S. Application Data
(63) Continuation of application No. 18/402,039, filed on Jan. 2, 2024.
(60) Provisional application No. 63/610,780, filed on Dec. 15, 2023.

(51) Int. Cl. H10D 62/10; H10D 30/01; H10D 30/43; H10D 30/62; H10D 64/01

(52) U.S. Cl. CPC H10D 62/121; H10D 30/014; H10D 30/024; H10D 30/43; H10D 30/62; H10D 64/017

(57) ABSTRACT

A device includes silicon nanostructures above in an n-type region, and silicon germanium nanostructures in a p-type region, wherein at least one of the silicon germanium nanostructures includes a silicon core region having a first concentration of germanium of about 20% or less, a silicon germanium region having a first interface between the silicon core region and the silicon germanium region, and a second silicon germanium region having a second interface between the silicon germanium region and the second silicon germanium region, the second silicon germanium region having a second concentration of germanium up to about 40%. A concentration gradient of germanium increases from the first concentration of germanium to the second concentration of germanium. A high-k dielectric layer surrounds at least one of the silicon nanostructures and at least one of the silicon germanium nanostructures.

### CROSS REFERENCE TO RELATED APPLICATIONS

This application is a continuation of U.S. Patent Application No. 18/402,039, filed on Jan. 2, 2024, entitled “Semiconductor Device and Method of Manufacture,” which claims priority to U.S. Provisional Patent Application No. 63/610,780, filed on Dec. 15,2023, which applications are incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 11A, 11B, 11C, 12A, 12B, 12C, 12D, 13A, 13B, 13C, 14A, 14B, 15A, 15B, 16A, 16B, 16C. FIG. 16D, FIG. 16E, FIG. 16F, ,FIG. 16G ,FIG. 16H 16I, 16J 16K, 17A, 17B, 17C, 18A, 18B, 18C, 19A, 19B, 19C, 20A, 20B, and 20C are cross-sectional views of intermediate stages in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are discussed in which channel structures for a PMOS device are formed by depositing germanium over a silicon nanostructure and annealing the resulting structure to form a silicon germanium channel. By depositing germanium over a silicon nanostructure and annealing the structure the resulting silicon germanium channel has a varying germanium concentration across the channel structure in the PMOS device. By controlling the germanium concentration across the silicon germanium channel structure better device performance may be achieved.

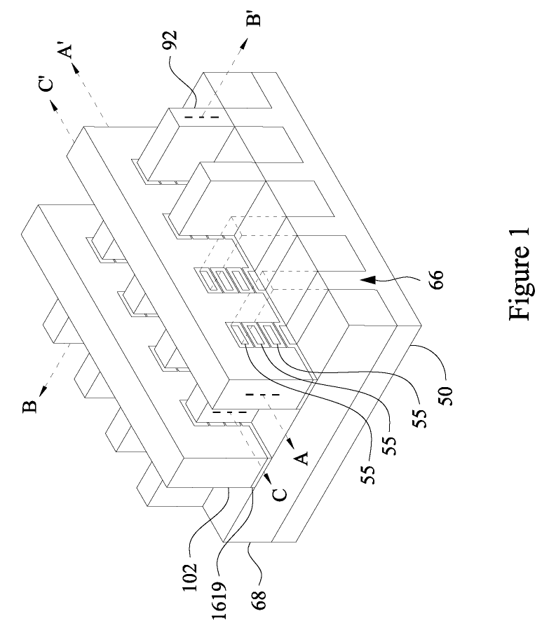

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

High-k dielectric layers 1619 are over top surfaces of the fins 66 and along top surfaces, sidewalls, and bottom surfaces of the nanostructures 55. Gate electrodes 102 are over the high-k dielectric layers 1619. Epitaxial source/drain regions 92 are disposed on the fins 66 on opposing sides of the high-k dielectric layers 1619 and the gate electrodes 102.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

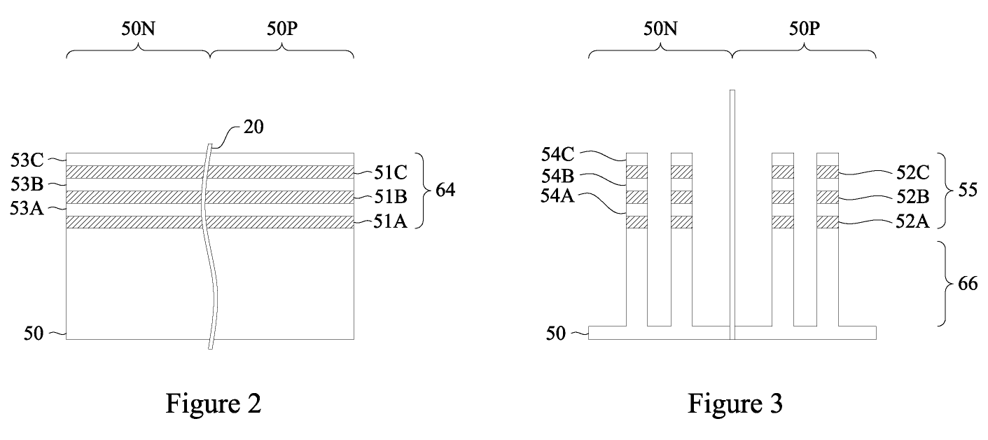

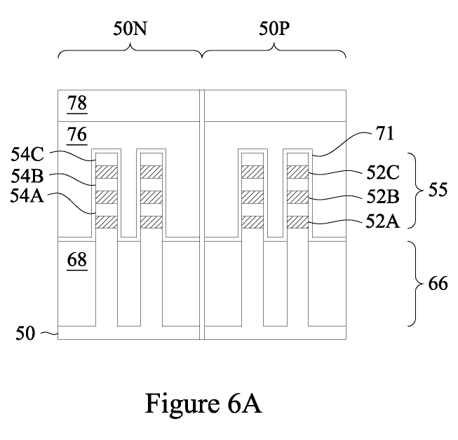

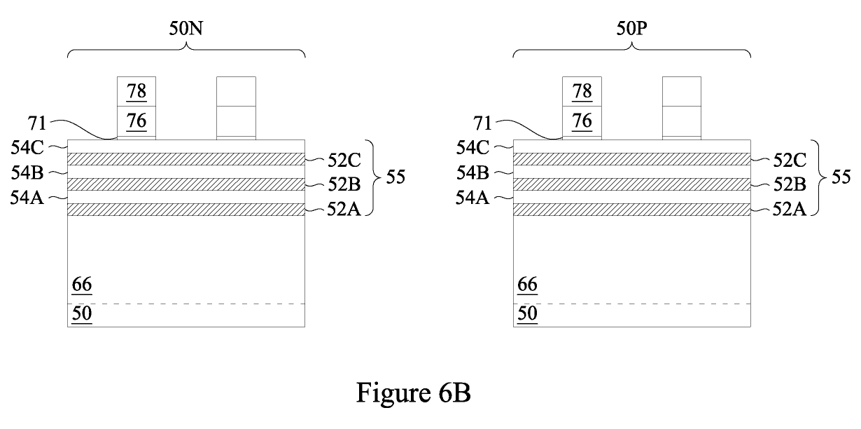

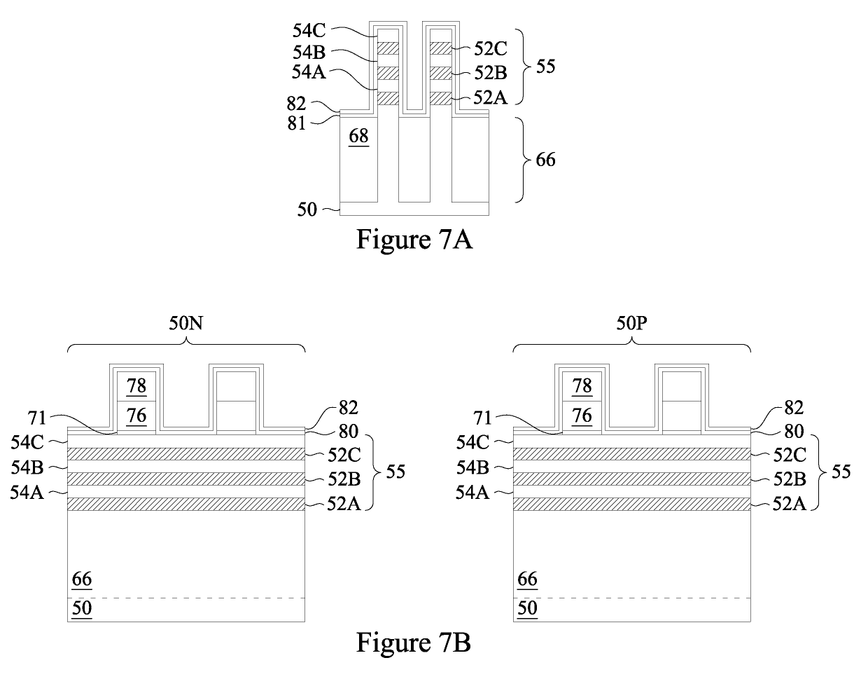

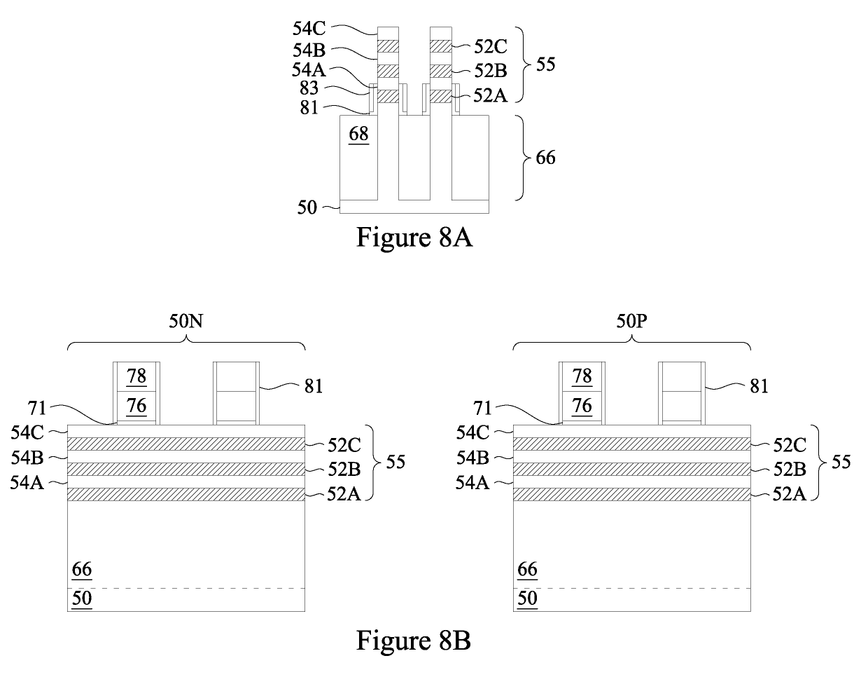

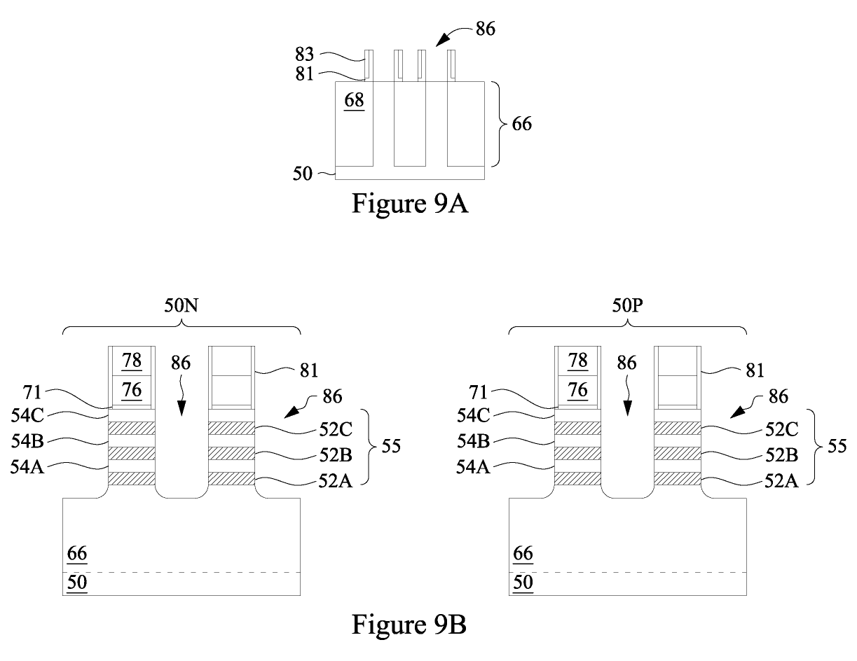

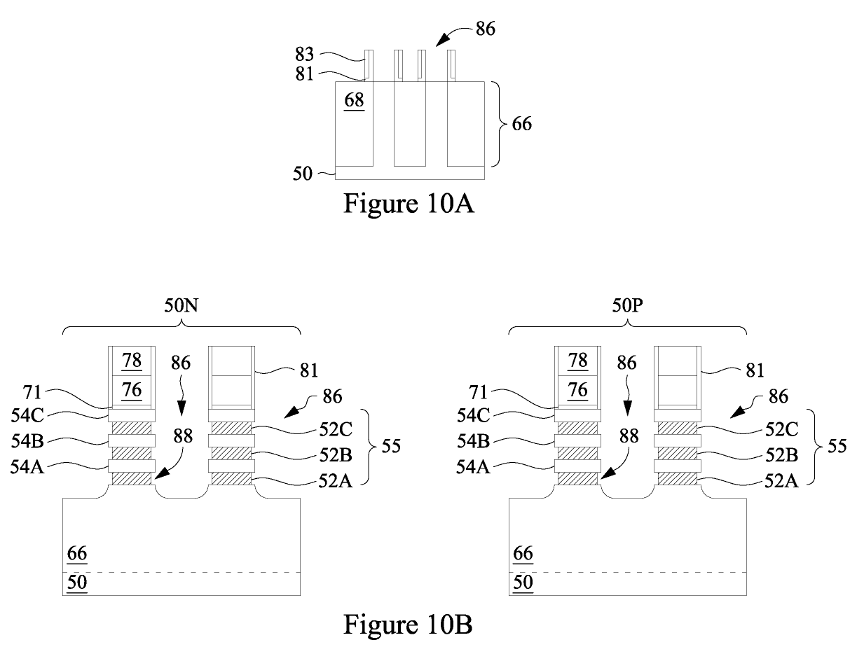

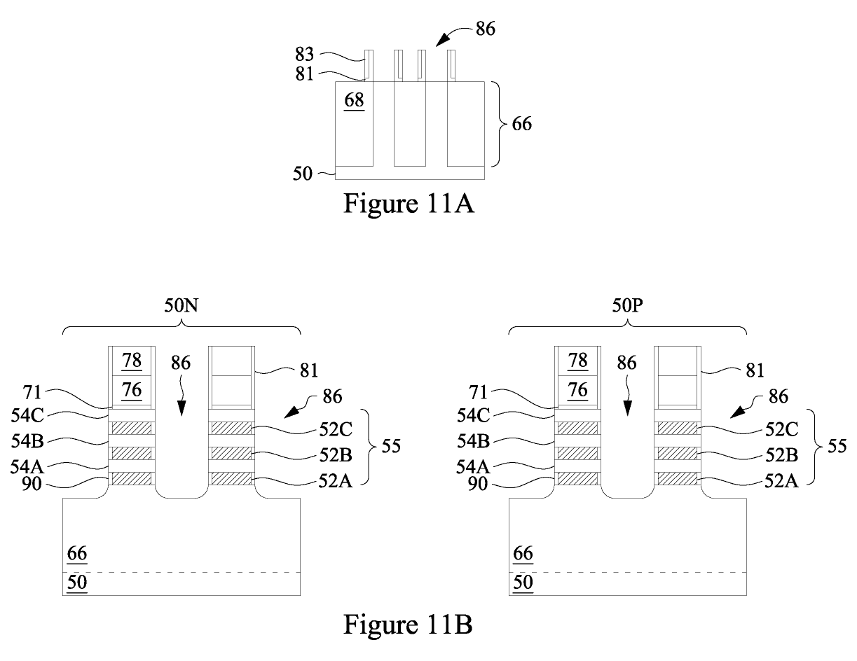

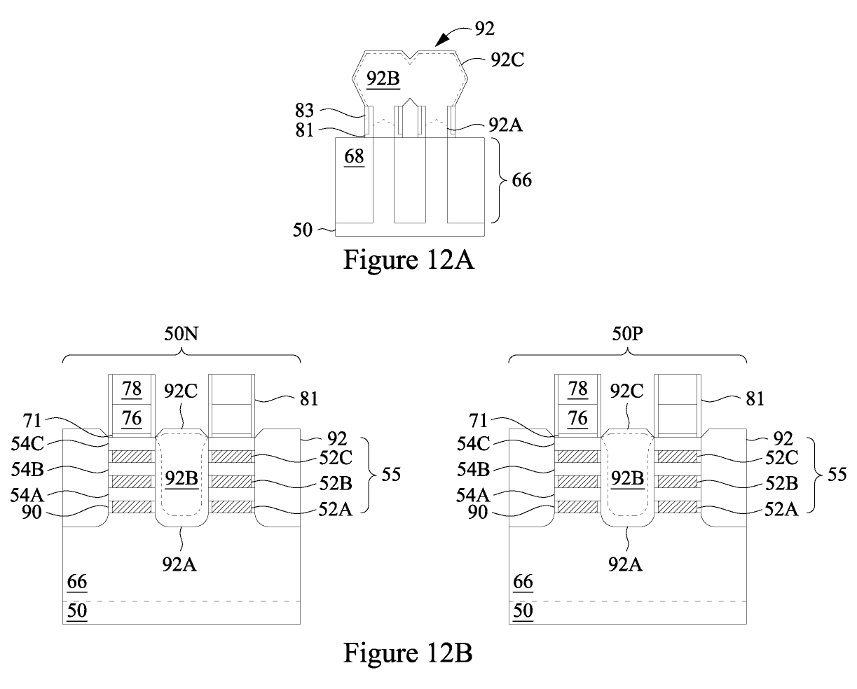

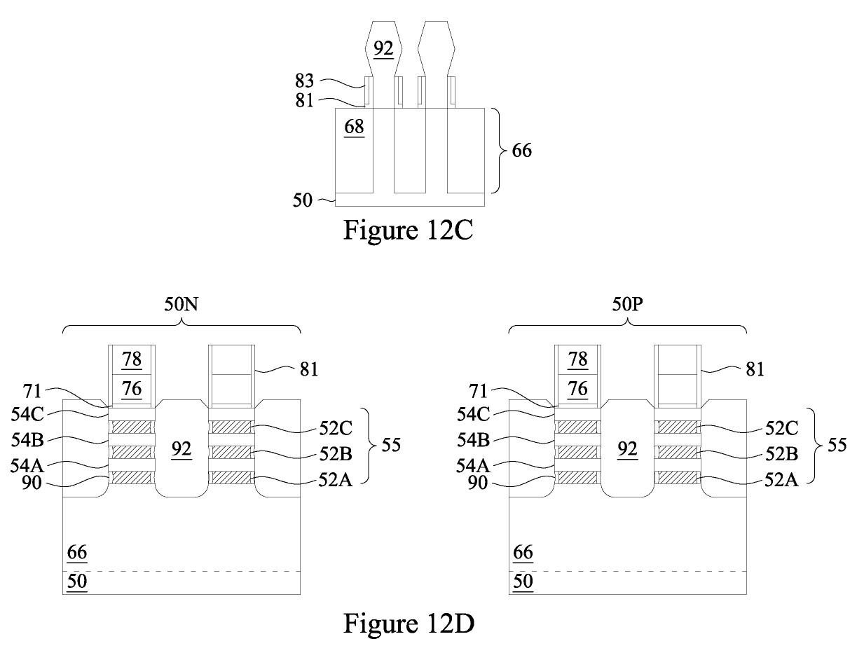

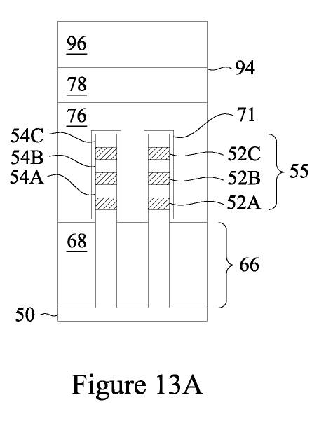

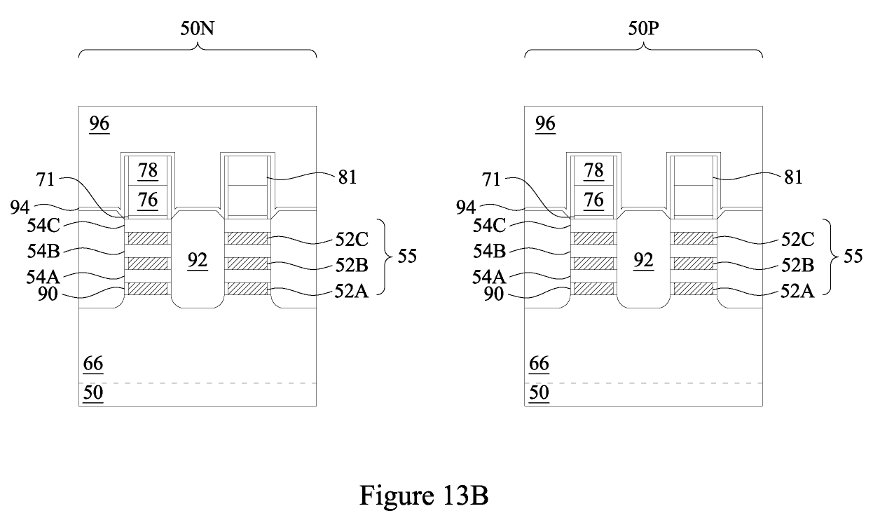

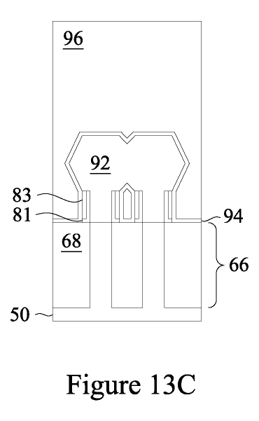

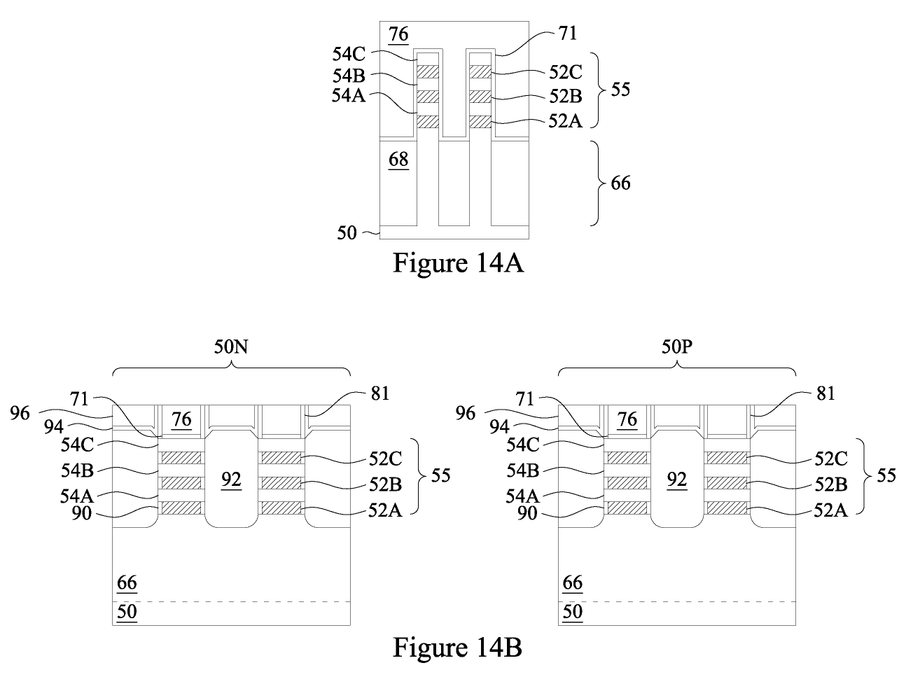

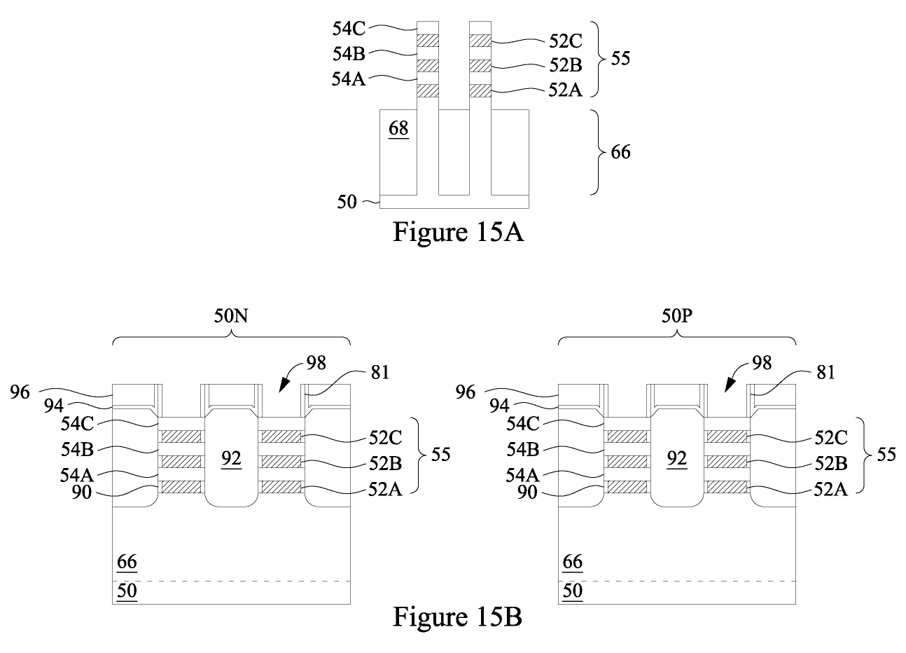

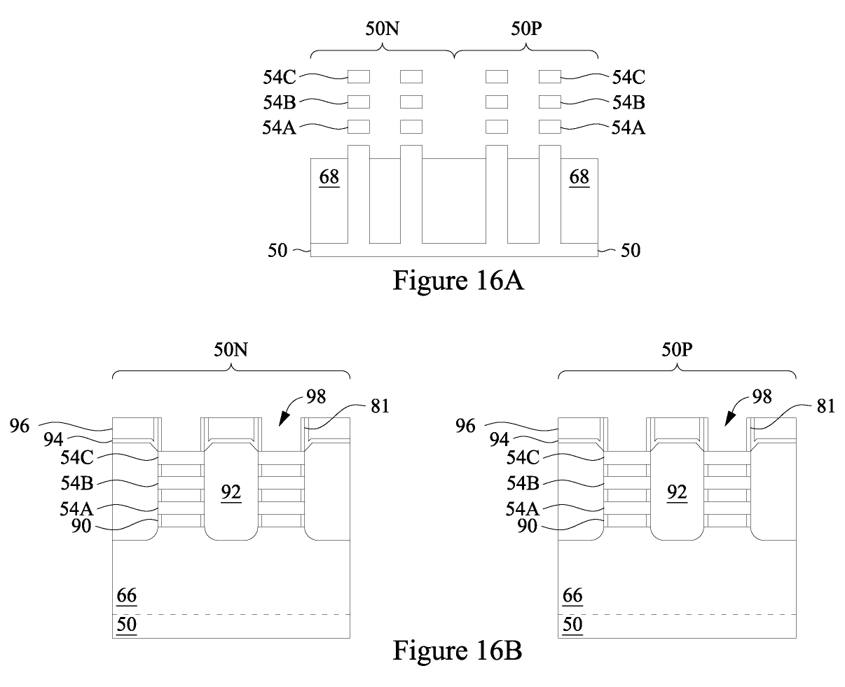

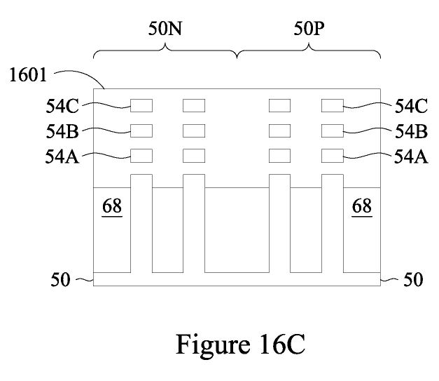

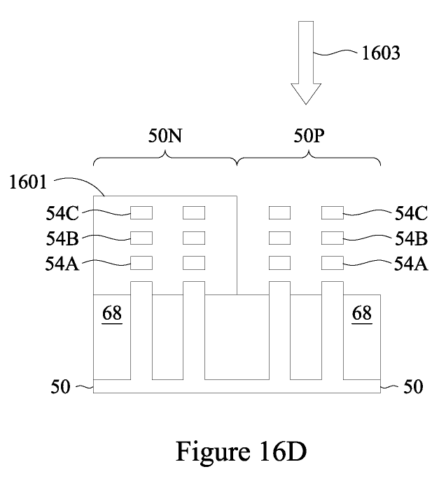

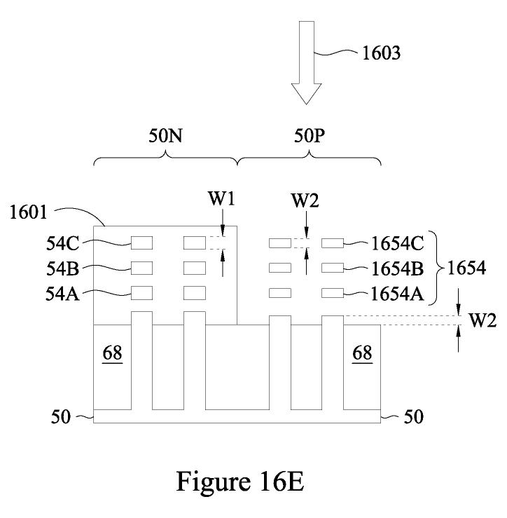

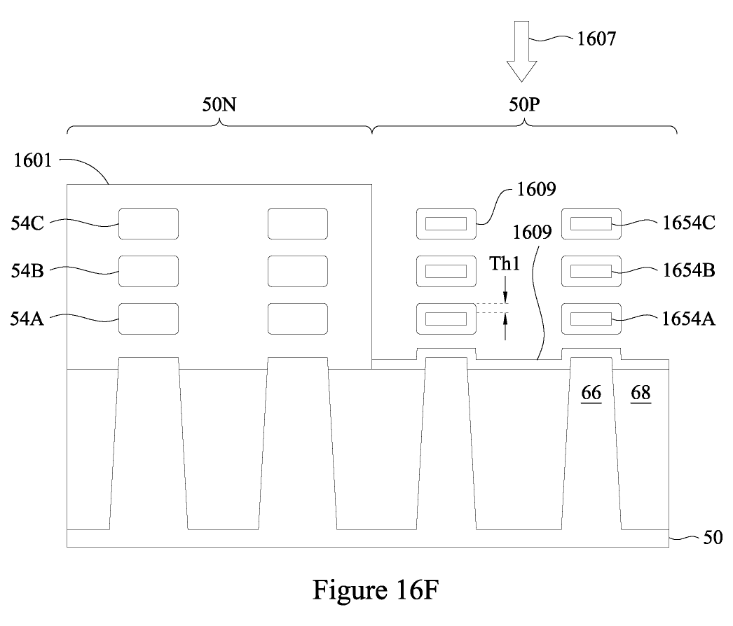

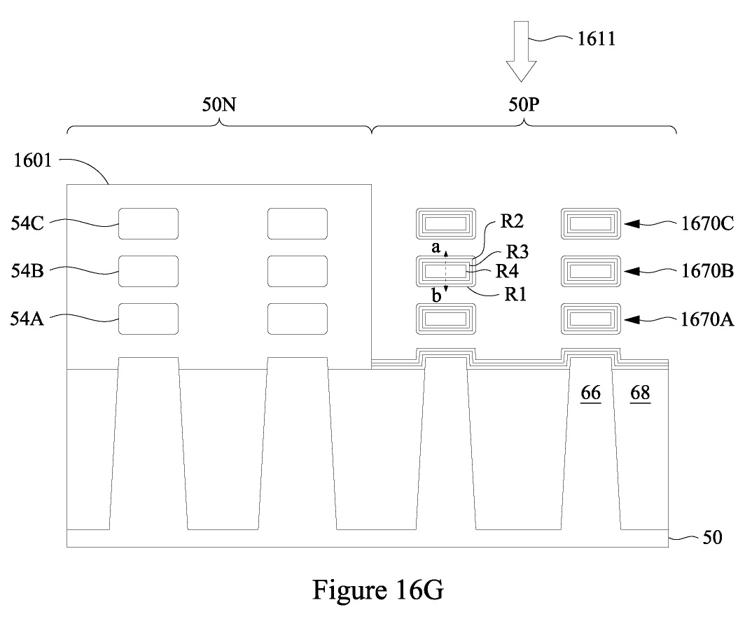

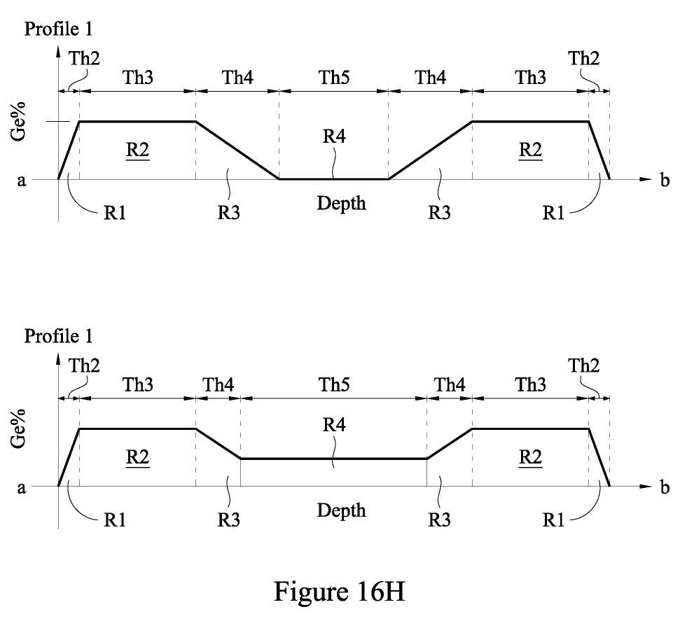

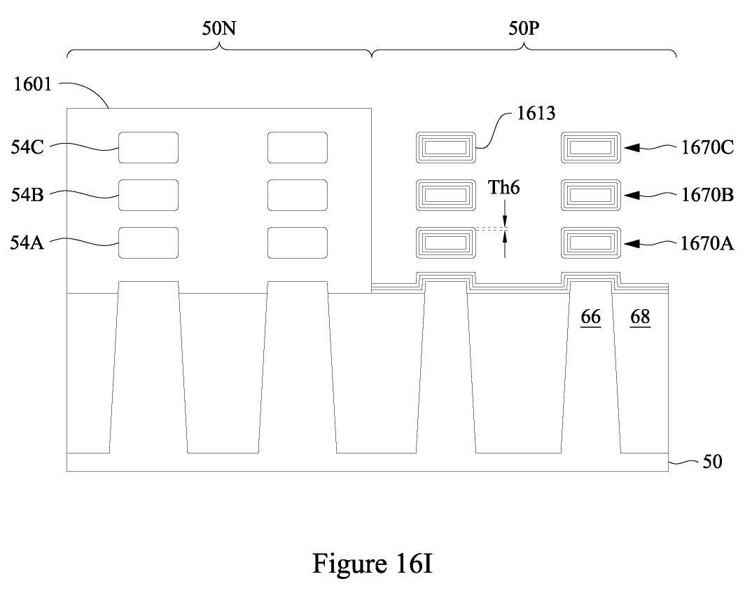

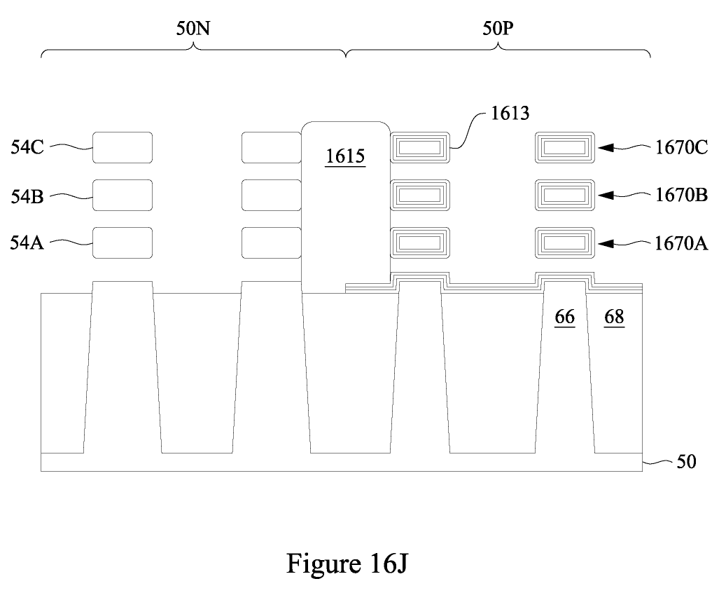

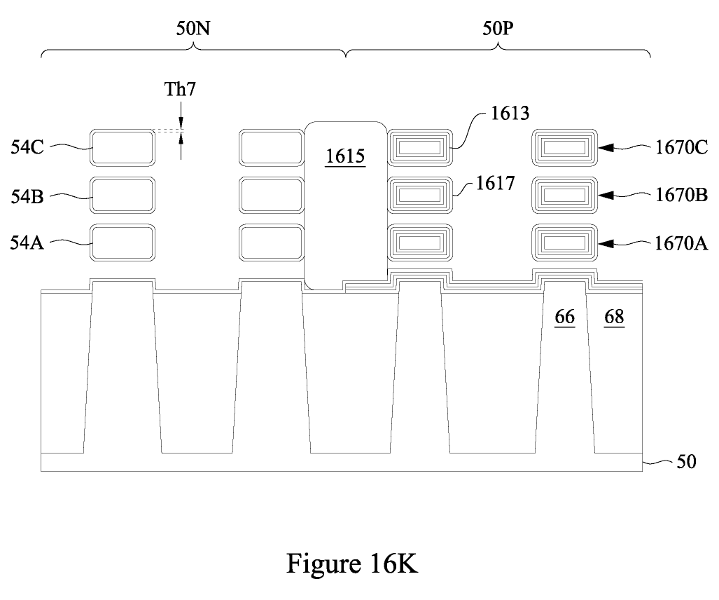

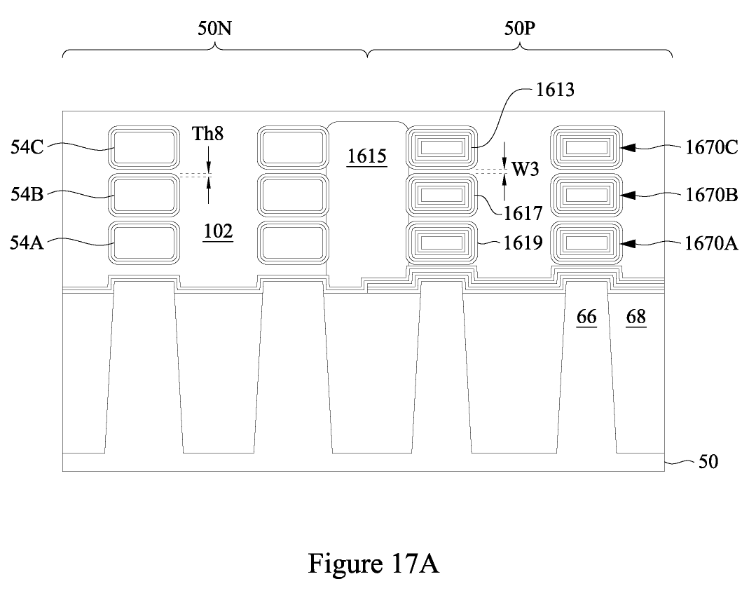

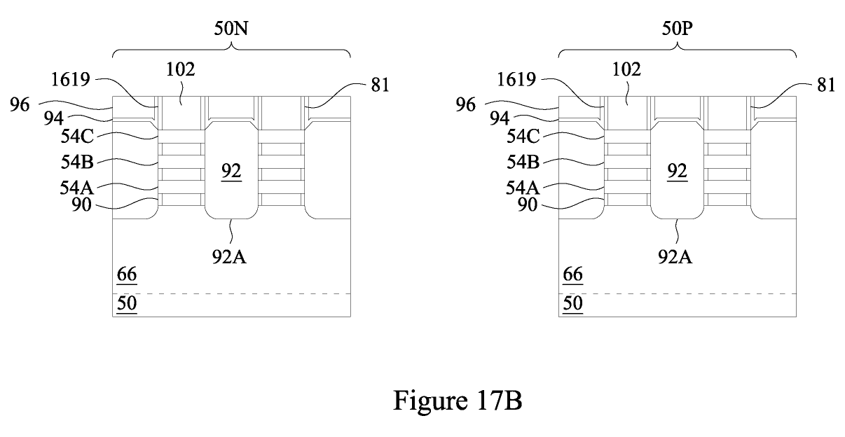

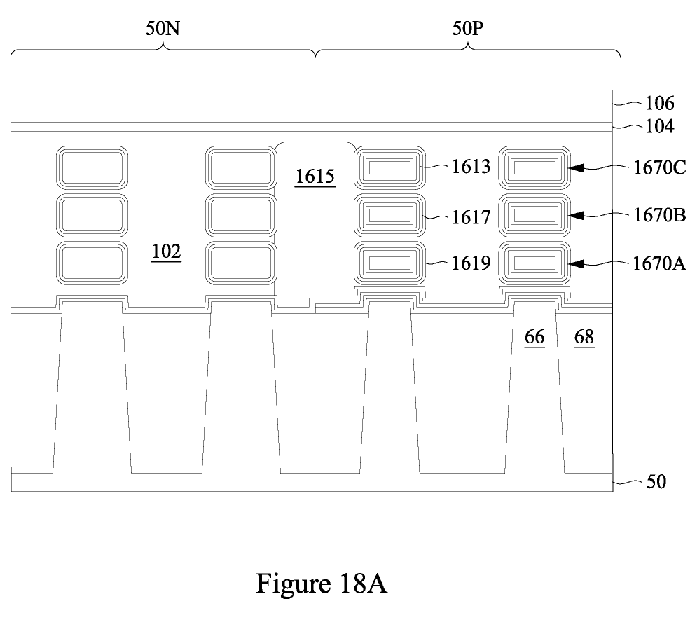

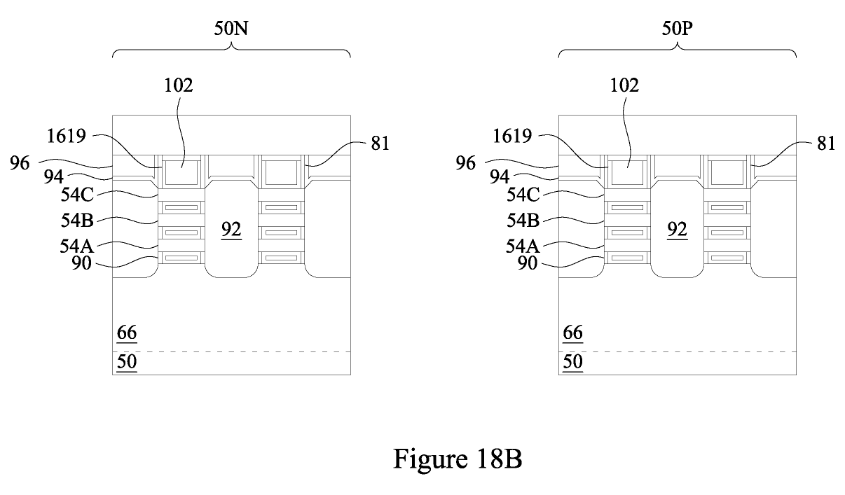

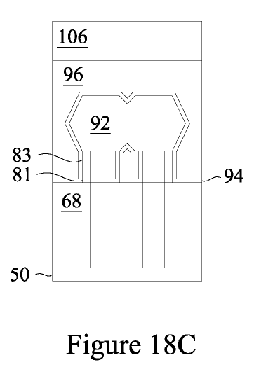

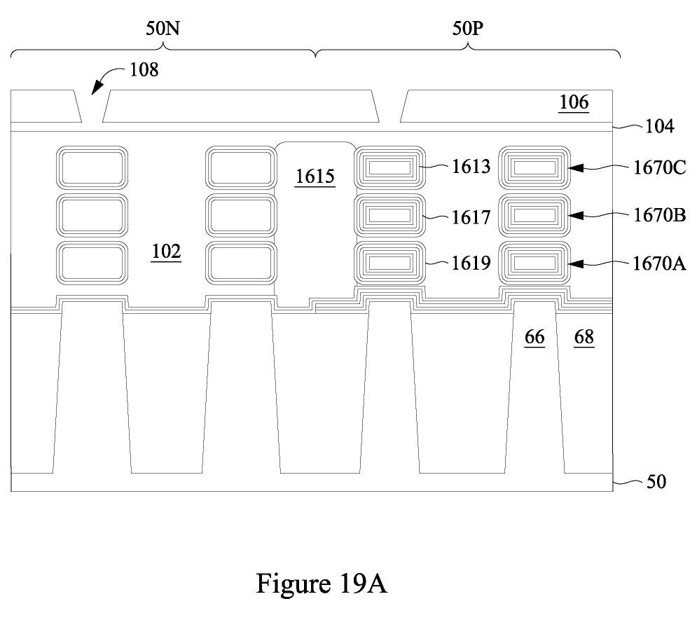

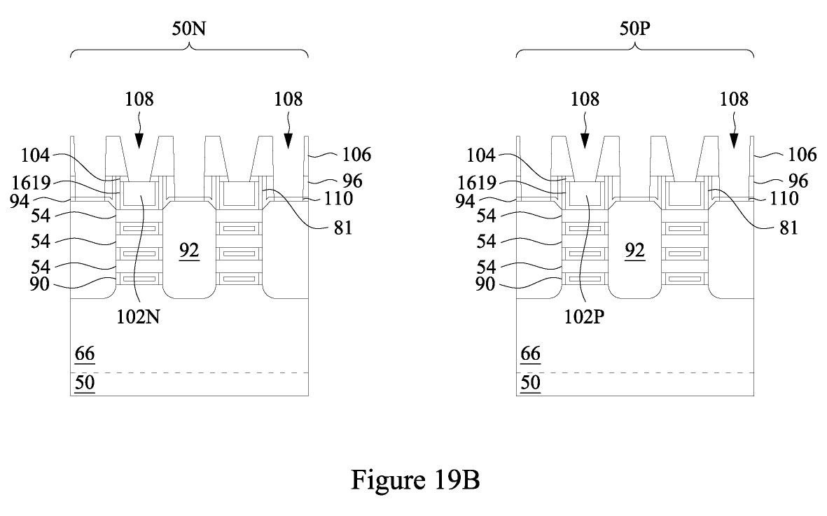

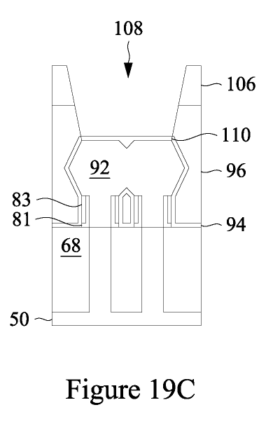

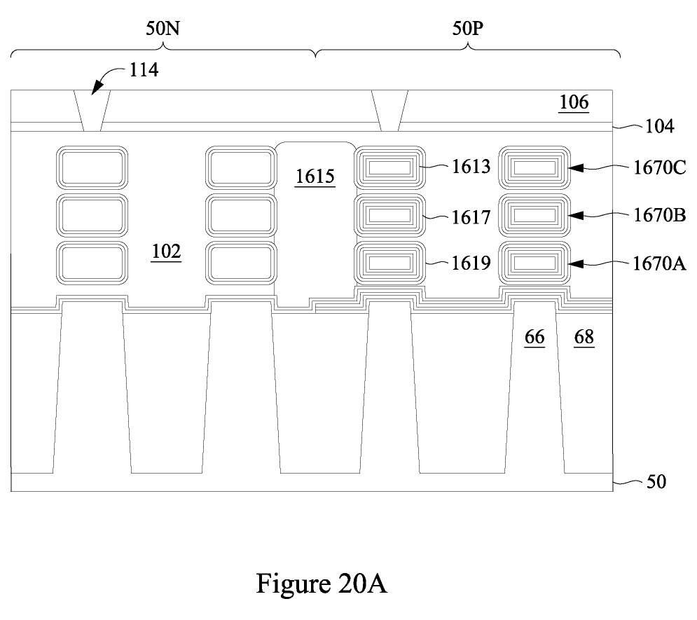

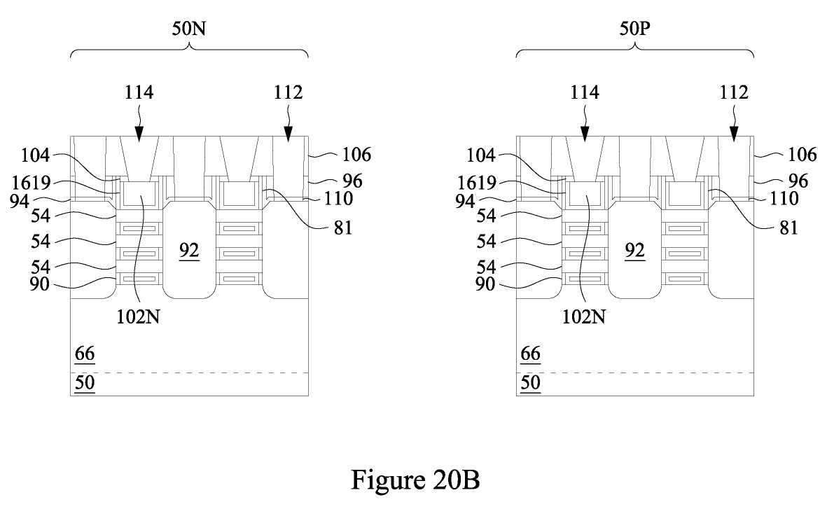

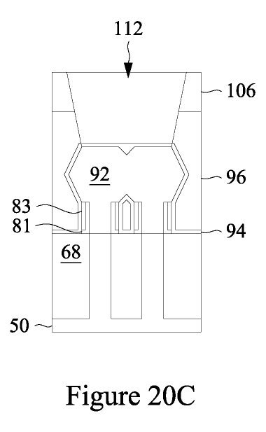

FIGS. 2 through 20C are cross-sectional views of intermediate stages in the manufacturing of nano-FETs, in accordance with some embodiments. FIGS. 2 through 5, 6A, 13A, 14A, 15A, 16A, 16C-16G, 16I-16J, 17A, 18A, 19A, and 20A illustrate reference cross-section A-A’ illustrated in FIG. 1. FIGS. 6B, 7B, 8B, 9B, 10B, 11B, 11C, 12B, 12D, 13B, 14B, 15B, 16B, 17B, 18B, 19B, and FIG. 20B illustrate reference cross-section B-B’ illustrated in FIG. 1. FIGS. 7A, 8A, 9A, 10A, 11A, 12A, 12C, 13C, 18C, 19C, and FIG. 20C illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium, or the like, and the second semiconductor layers 53 may be formed of a second semiconductor material, such as silicon, silicon carbon, or the like.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions.

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

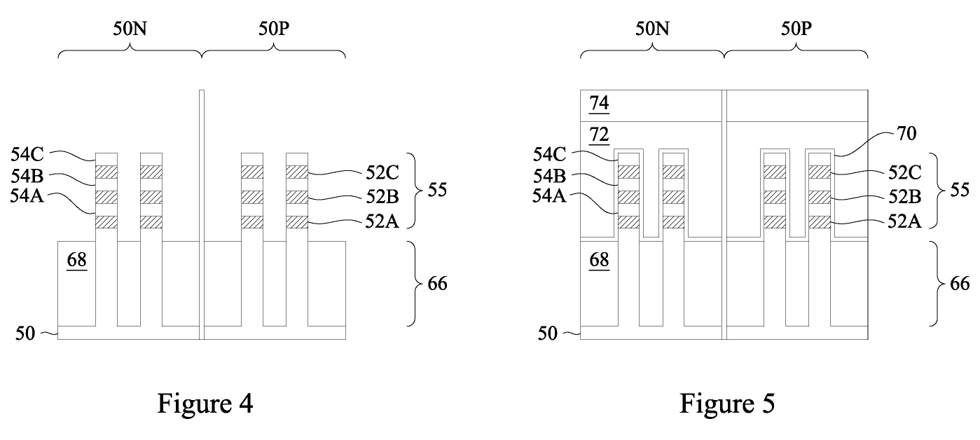

In FIG. 4, The STI regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the substrate 50. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1x10¹⁵ atoms/cm³ to about 1x10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88. Although sidewalls of the first nanostructures 52 in sidewall recesses 88 are illustrated as being straight in FIG. 10B, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54.

Moreover, although the outer sidewalls of the first inner spacers 90 are illustrated as being straight in FIG. 11B, the outer sidewalls of the first inner spacers 90 may be concave or convex. The first inner spacers 90 may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12C) by subsequent etching processes, such as etching processes used to form gate structures.

In FIGS. 12A-12C, epitaxial source/drain regions 92 are formed in the first recesses 86. In some embodiments, the source/drain regions 92 may exert stress on the second nanostructures 54, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gate layer 72 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same NSFET to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

In FIGS. 13A-13C, a first interlayer dielectric (ILD) 96 is deposited over the structure illustrated in FIGS. 6A, 12B, and 12A (the processes of FIGS. 7A-12D do not alter the cross-section illustrated in FIGS. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the mask layer 74, and the first spacers 81. The CESL 94 may comprise a dielectric material, such as, silicon nitride, silicon oxide, silicon oxynitride, or the like, having a different etch rate than the material of the overlying first ILD 96.

In FIGS. 14A-14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gate layer 72 are exposed through the first ILD 96. In some embodiments, the masks 78 may remain, in which case the planarization process levels the top surface of the first ILD 96 with top surface of the masks 78 and the first spacers 81.

In FIGS. 15A and 15B, the dummy gate layer 72, and the mask layer 74 if present, are removed in one or more etching steps, so that second recesses 98 are formed. Portions of the dummy dielectric layers 60 in the second recesses 98 are also be removed. In some embodiments, the dummy gate layer 72 and the dummy dielectric layers 60 are removed by an anisotropic dry etch process. For example, the etching process may include a dry etch process using reaction gas(es) that selectively etch the dummy gate layer 72 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gate layer 72 are etched. The dummy dielectric layers 60 may then be removed after the removal of the dummy gate layer 72.

In FIGS. 16A and 16B, the first nanostructures 52 in the n-type region 50N and in the p-type region 50P are removed extending the second recesses 98 to between the second nanostructures 54. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

In FIG. 16C, after the first nanostructures 52 in the n-type region 50N and in the p-type region 50P have been removed, a hard mask layer 1601 may be formed over the second nanostructures 54. In an embodiment, the hard mask layer 1601 may comprise of a nitride such as silicon nitride and may be formed by deposition such as by plasma-enhanced chemical vapor deposition (PECVD), atomic layer deposition (ALD), or the like. However, any suitable material and process may be utilized to form the hard mask layer 1601.

In FIG. 16D, a first hard mask patterning process 1603 is performed to remove a portion of the hard mask layer 1601 over the p-type region 50P exposing the second nanostructures 54 in the p-type region 50P while the second nanostructures 54 in the n-type region 50N remain covered by the hard mask layer 1601. In an embodiment, the first hard mask patterning process 1603 may be a photolithographic patterning process. However, any suitable mask removal process may be utilized to remove the hard mask layer 1601 over the p-type region 50P.

In FIG. 16E, a nanostructure trim process 1605 is performed on the second nanostructures 54 exposed in the p-type region 50P forming nanostructure cores 1654 (e.g., nanostructure cores 1654A-1654C). In an embodiment, the nanostructure trim process 1605 reduces dimensions (e.g., first widths W1) of the second nanostructures 54 to dimensions (e.g., second widths W2) of the resulting nanostructure cores 1654. In an embodiment, the nanostructure trim process 1605 may also reduce dimensions (e.g., from the first width W1 to the second width W2) of the fins 66 protruding above the STI regions 68 exposed in the p-type region 50P. In some embodiments, following the nanostructure trim process 1605 the second nanostructures 54 exposed in the p-type region 50P is reduced from the first width W1 to the second width W2 of the nanostructure cores 1654. In an embodiment, the first width W1 is in a range of 3 nm to 10 nm. In an embodiment, the second width W2 is about 8 nm or less (where one of ordinary skill in the art would understand “about” to refer to standard process variations associated with dimensioning widths and thicknesses).

In an embodiment, the nanostructure trim process 1605 may be any acceptable etching process, such as one that is selective to the second nanostructures 54 (e.g., selectively etches the material of the second nanostructures 54). The etching may be isotropic.

In some embodiments, the nanostructure trim process 1605 includes performing multiple oxidation and etch cycles. For example, during each oxidation cycle, portions of the second nanostructures 54 exposed in the p-type region 50P may be oxidized, and during each etch cycle, the oxidized portions of the second nanostructures 54 are removed. The oxidation and etch cycles are repeated until a desired amount of material has been trimmed from the second nanostructures 54 in the p-type region 50P resulting in the nanostructure cores 1654. For example, the oxidation and etch cycles may be cyclically repeated a predetermined quantity of times. The oxidation may be accomplished by any acceptable oxidation process, such as a native oxidation process, a thermal oxidation process, a rapid thermal oxidation (RTO) process, a chemical oxidation process, an in-situ stream generation (ISSG) process, or the like. Other oxidation processes or a combination thereof may be performed. The etching may be accomplished by any acceptable etching process, such as a wet etch, a dry etch, or combinations thereof. For example, a chemical oxide removal with any acceptable etch process using, for example, dilute hydrofluoric (dHF) acid may be used.

In FIG. 16F, a silicon germanium (SiGe) deposition process 1607 is performed over the nanostructure cores 1654, the exposed portions of the fins 66 and the exposed portions of the STI regions 68.In an embodiment, the SiGe deposition process 1607 forms a germanium source layer 1609 on the nanostructure cores 1654 and the exposed portion of the fins 66. In an embodiment, the SiGe deposition process 1607 is performed through a CVD process. The SiGe deposition process 1607 may be performed in a CVD chamber. In an embodiment, the SiGe deposition process 1607 utilizes GeH₄ as a first reactant gas as a source for germanium. However, any suitable first reactant gas may be utilized as the source for the germanium. In an embodiment, the SiGe deposition process 1607 utilizes SiH₄ as a second reactant gas as a source for silicon. However, any suitable second reactant gas may be utilized as the source for the silicon. A carrier gas utilized during the SiGe deposition process 1607 may be H₂ gas or N₂ gas, or another suitable carrier gas. The SiGe deposition process 1607 may be performed at a first process temperature in a range from about 300 °C to about 600 °C and at a first process pressure in a range of about 3 Torr to about 100 Torr. In an embodiment, the SiGe deposition process 1607 may be carried out for a time in the range of about 1,000 seconds to about 4,000 seconds (where one of ordinary skill in the art would understand “about” to refer to standard process variations associated with process parameters of temperature, pressure, and time). Following the SiGe deposition process 1607, the germanium source layer 1609 may be formed to a first thickness Th1, wherein the first thickness Th1 is in a range of about .5 nm to about 3 nm.

Further, in an embodiment, during the SiGe deposition process 1607, a flow rate of the first reactant gas and a flow rate of the second reactant gas may be controlled to produce the germanium source layer 1609 that will produce a desired germanium concentration profile following a subsequently discussed annealing process 1611 (discussed in greater detail with respect to FIG. 16G). In one such embodiment, the flow rate of the first reactant gas compared to the flow rate of the second reactant gas is reduced towards the end of the SiGe deposition process 1607 to reduce the concentration of germanium towards an exterior surface of the germanium source layer 1609. In such an embodiment, the germanium source layer 1609 may have a germanium concentration reduced to about zero percent germanium at the exterior surface of the germanium source layer 1609. By reducing the germanium concentration at the exterior surface of the germanium source layer 1609 scattering between subsequently formed layers (e.g. a silicon cap layer 1613) formed over the exterior surface of the germanium source layer 1609 resulting from a difference in crystal orientations from different lattice structures of materials at an interface between the germanium source layer 1609 and the subsequently formed layers (e.g., the silicon cap layer 1613) may be reduced.

In FIG. 16G, the annealing process 1611 is performed on the germanium source layer 1609 and the nanostructure cores 1654, where the annealing process 1611 forms silicon germanium (SiGe) nanostructures 1670 (e.g., SiGe nanostructures 1670A-C, which may be referred to as a SiGe channel structure). In an embodiment, during the annealing process 1611 germanium from the germanium source layer 1609 diffuses into silicon from the nanostructure cores 1654 forming the SiGe nanostructures 1670. The annealing process 1611 is performed so that a concentration of germanium varies across the SiGe nanostructures 1670. A concentration profile of germanium across the SiGe nanostructures 1670 may be seen across a profile ‘a-b’ of the SiGe nanostructure 1670 denoted in FIG. 16G and discussed in greater detail with below with respect to FIG. 16H.

In an embodiment, the annealing process 1611 may be an in-situ annealing process performed in the CVD chamber of the SiGe deposition process 1607. The annealing process 1611 may be performed at a second process temperature in a range of about 500 °C to about 900 °C and at a second process pressure in a range of about 3 Torr to about 100 Torr. The carrier gas utilized during the annealing process 1611 may be H₂ gas, however, any suitable carrier gas may be utilized. In an embodiment, the annealing process 1611 may be carried out for a time in the range of about 60 seconds or less. In an embodiment, the increased second process temperature from the first process temperature may drive diffusion of the germanium from the germanium source layer 1609 into the nanostructure cores 1654. In an embodiment where the nanostructure cores 1654 comprises silicon, the diffusion of the germanium from the germanium source layer 1609 may mitigate the difference in lattice structure at an interface between the germanium source layer 1609 and the nanostructure cores 1654. A gradient change in lattice structure by the diffusion of the germanium from the germanium source layer 1609 into the nanostructure cores 1654 may reduce scattering within the resulting SiGe nanostructures 1670. Following the annealing process 1611, the concentration profile of germanium may be divided into four regions, a first region R1, a second region R2, a third region R3, and a fourth region R4. Each of the four regions characterized by differing germanium percentages (as discussed in greater detail with respect to FIG. 16H).

In FIG. 16H, two germanium concentration profiles are depicted across the profile ‘a-b’ of the SiGe nanostructure 1670 moving from the “a-b” cross section of FIG. 16G. Both profile 1 and profile 2 depict the four regions and the associated thicknesses of each region.

In an embodiment, the first region R1 has a second thickness Th2 in a range of about 0 nm to about 1 nm. In an embodiment, both the profile 1 and the profile 2 are characterized by the first region R1 having a germanium percentage of about 0% germanium at an exterior surface of the SiGe nanostructures 1670 (where one of ordinary skill in the art would understand “about” to refer to standard process variations and nominal diffusion effects associated with chemical concentrations) where the germanium percentage increases across the first region R1 into the SiGe nanostructures 1670 until an interface with the second region R2 where the germanium percentage is at a maximum with a germanium percentage in a range of about 5% to about 40% germanium.

In an embodiment, the second region R2 has a third thickness Th3 in a range of about 1 nm to about 4 nm. In an embodiment, both the profile 1 and the profile 2 are characterized by the second region R2 having a constant germanium percentage (within process variation and nominal diffusion) across the span of the second region R2 in the SiGe nanostructures 1670, where the constant germanium percentage is in a range of about 5% to about 40%. The germanium percentage remains constant across the second region R2 from the interface with the first region R1 to an interface with the third region R3.

In an embodiment, the third region R3 has a fourth thickness Th4 in a range of about 0 nm to about 2 nm. In an embodiment, the germanium percentage in the third region R3 decreases from a germanium percentage of about 5% to about 40% at the interface with the second region R2 to a maximum germanium percentage at an interface with the fourth region R4 of about 20% to about 0% germanium.

In an embodiment, the fourth region R4 has a fifth thickness Th5 in a range of about 0 nm to about 8 nm. In an embodiment, the fourth region R4 illustrated in the profile 1 represents the fourth region R4 having a constant maximum germanium percentage of about 0% from the interface with the third region R3 to a mirroring interface with an oppositely positioned third region R3. In this embodiment, the fourth region may comprise of pure silicon (within process variations). In another embodiment, the fourth region R4 illustrated in the profile 2 represents the fourth region R4 having a constant maximum germanium percentage of about 20% from the interface with the third region to a mirroring interface with an oppositely positioned third region R3. It should be noted that the fourth region R4 may have a constant germanium percentage between the opposing third regions R3 in between about o% germanium and about 20% germanium.

In FIG. 16I, a silicon cap layer 1613 may be deposited over the SiGe nanostructure 1670. In an embodiment, the silicon cap layer 1613 may be deposited by CVD, however any suitable method of deposition may be utilized. In an embodiment, the deposition of the silicon cap layer 1613 may be performed in the CVD chamber. In an embodiment, the deposition of the silicon cap layer 1613 utilizes SiH₄ or Si₂H₆ as a reactant gas for the sources of the silicon. The carrier gas utilized during the deposition of the silicon cap layer 1613 may be H₂ gas or N₂ gas, or another suitable carrier gas. The deposition process of the silicon cap layer 1613 may be performed at a third process temperature in a range from about 300 °C to about 600 °C and at a third process pressure in a range of about 3 Torr to about 100 Torr. In an embodiment, the deposition of the silicon cap layer 1613 may be carried out for a time in the range of about 100 seconds to about 300 seconds. The silicon cap layer 1613 may be formed to a sixth thickness Th6, wherein the sixth thickness Th6 is in a range of about .5 nm to about 2 nm. If the thickness of the silicon cap layer 1613 is less than the sixth thickness Th6, then adequate protection from defect formation to the SiGe nanostructures 1670 may not occur. If the thickness of the silicon cap layer 1613 is greater than the sixth thickness Th6, then adequate space between channel structures may not be achieved. In an embodiment, formation of the silicon cap layer 1613 helps prevent defects that protecting the silicon germanium nanostructure 1670 from oxidizing. Protecting the silicon germanium nanostructure 1670 from oxidizing also helps improve the interface with the subsequently formed interface layer 1617 (discussed in greater detail below with respect to FIG. 16k).

In FIG. 16J, the hard mask layer 1601 is removed and a dielectric structure 1615 may be performed between the second nanostructures 54 in the n-type region 50N and the SiGe nanostructures 1670 in the p-type region. In an embodiment, the hard mask layer 1601 may be removed using an ashing process followed by a wet clean process, or other suitable photoresist removal processes. Further, the dielectric structure 1615 may comprise of a silicon compound, a nitrogen compound, a carbon compound, an oxygen compound, the like or a combination thereof. The dielectric structure 1615 may serve to isolate the NMOS device in the n-type region 50N and the PMOS device in the p-type region 50P.

In FIG. 16K, the interface layer 1617 is formed over the second structures 54, the SiGe nanostructures 1670 (and the silicon cap layer 1613 if present), and over the fins 66. In an embodiment, the interface layer is formed to improve the interface quality between the subsequently formed high-k dielectric layer 1619 (illustrated in FIG. 17A) and associated channels structures of the second nanostructures 54 and the SiGe nanostructures 1670. In an embodiment, the interface layer 1617 comprises silicon oxide, however any suitable material may be utilized. Further, the interface layer 1617 may be formed to a seventh thickness Th7, the seventh thickness in a range of about .5 nm to about 2 nm. If the interface layer 1617 has insufficient thickness than adequate interface quality between the channel structures and the high-k dielectric layers 1619 may not occur. If the thickness of the interface layer 1617 is too great than adequate space between the channel structures may not be achieved.

In FIGS. 17A and 17B, high-k dielectric layers 1619 and gate electrodes 102 are formed for replacement gates. The high-k dielectric layers 1619 are deposited conformally in the second recesses 98. In the n-type region 50N, the high-k dielectric layers 1619 may be formed on top surfaces and sidewalls of the substrate 50 and on top surfaces, sidewalls, and bottom surfaces of the second nanostructures 54, and in the p-type region 50P, the high-k dielectric layers 1619 may be formed on top surfaces and sidewalls of the substrate 50 and on top surfaces, sidewalls, and bottom surfaces of the SiGe nanostructures 1670. The high-k dielectric layers 1619 may also be deposited on top surfaces of the first ILD 96, the CESL 94, the first spacers 81, and the STI regions 68.

In accordance with some embodiments, the high-k dielectric layers 1619 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the high-k dielectric layers 1619 include a high-k dielectric material, and in these embodiments, the high-k dielectric layers 1619 may have a k value greater than about 7.0, and may include a metal oxide or a silicate of hafnium, aluminum, zirconium, lanthanum, manganese, barium, titanium, lead, and combinations thereof. The structure of the high-k dielectric layers 1619 may be the same or different in the n-type region 50N and the p-type region 50P. The formation methods of the high-k dielectric layers 1619 may include molecular-beam deposition (MBD), ALD, PECVD, and the like. Further, the high-k dielectric layers 1619 may be formed to an eighth thickness Th8, the eighth thickness Th8 in a range of about .5 nm to about 2 nm. Following the formation of the high-k dielectric layers 1619 a channel gap between the SiGe nanostructures 1670 may have a third width W3 in a range of about 3 nm to about 10 nm. In an embodiment, the SiGe nanostructures 1670 may achieve a threshold voltage in a range of about 100 millivolts to about 300 millivolts.

The gate electrodes 102 are deposited over the high-k dielectric layers 1619, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, copper, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the SiGe nanostructures 1670.

The formation of the high-k dielectric layers 1619 in the n-type region 50N and the p-type region 50P may occur simultaneously such that the high-k dielectric layers 1619 in each region are formed from the same materials, and the formation of the gate electrodes 102 may occur simultaneously such that the gate electrodes 102 in each region are formed from the same materials. In some embodiments, the high-k dielectric layers 1619 in each region may be formed by distinct processes, such that the high-k dielectric layers 1619 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the high-k dielectric layers 1619 and the material of the gate electrodes 102, which excess portions are over the top surface of the first ILD 96. The remaining portions of material of the gate electrodes 102 and the high-k dielectric layers 1619 thus form replacement gate structures of the resulting nano-FETs. The gate electrodes 102 and the high-k dielectric layers 1619 may be collectively referred to as “gate structures.”

In FIGS. 18A-18C, the gate structure is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts penetrate through the gate mask 104 to contact the top surface of the recessed gate electrodes 102.

As further illustrated by FIGS. 18A-18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 19B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 20A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer (not separately illustrated) and a conductive material (not separately illustrated) and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

While illustrated embodiments show same number of channel regions having uniform thickness, widths, and spacing in the n-type region (50N) and in the p-type region (50P) this is merely illustrative and various structures across the n-type region (50N) and the p-type region (50P) as well as various structures within the n-type region (50N) and the p-type region (50P) may have varying dimensions. Additionally it should be noted, that while embodiments above are discussed as performing each process on every structure, this is merely illustrative and not every structure (e.g., every nanostructure within the n-type region) requires every process to be performed on said structure.

Embodiments may achieve advantages. For example, by varying the germanium concentration across the four regions (e.g., the first region R1, the second region R2, the third region R3, and the fourth region R4) within the SiGe nanostructures 1670 better device performance may be achieved by having greater control over device functions, such as improving the ability to reliably achieve a threshold voltage in a range of 100 mini volt to 300 mini volt. The utilization of the silicon cap layer 1613 help prevent the surface of the SiGe nanostructures 1670 from oxidizing and developing defects. Further, the implementation of the interface layer 1617 improves interface quality between the SiGe nanostructures 1670 and the high-k dielectric layers 1619.

In accordance with an embodiment, a device includes plurality of silicon nanostructures above a semiconductor substrate in an n-type region of the semiconductor substrate, a plurality of silicon germanium nanostructures above the semiconductor substrate in a p-type region of the semiconductor substrate, wherein at least one of the plurality of silicon germanium nanostructures includes a silicon core region having a first concentration of germanium, wherein the first concentration of germanium is about 20% or less, a first silicon germanium region having a first interface between the silicon core region and the first silicon germanium region, and a second silicon germanium region having a second interface between the first silicon germanium region and the second silicon germanium region, the second silicon germanium region having a second concentration of germanium, wherein the second concentration of germanium is up to about 40%; wherein a first concentration gradient of germanium increases from the first concentration of germanium at the first interface to the second concentration of germanium at the second interface, a high-k dielectric layer surrounding at least one of the plurality of silicon nanostructures and at least one

of the plurality of silicon germanium nanostructures, and a gate electrode filling in a gap between adjacent ones of the plurality of silicon germanium nanostructures. In an embodiment, the at least one of the plurality of silicon germanium nanostructures further includes a third silicon germanium region having a third interface between the second silicon germanium region and the third silicon germanium region and an exterior surface opposite the third interface, wherein a second concentration gradient of germanium decreases from the second concentration of germanium at the third interface to about 0% germanium at the exterior surface. In an embodiment, the gap between at least one of the plurality of silicon germanium nanostructures is in a range of about 3 nm to about 10 nm. In an embodiment, respective ones of the plurality of silicon nanostructures has a same width as respective ones of the plurality of silicon germanium nanostructures. In an embodiment, further including a silicon cap layer surrounding at least one of the plurality of silicon germanium nanostructures. In an embodiment, the silicon cap layer has a thickness in a range about .5 nm to about 2 nm. In an embodiment, further including an interface layer disposed between at least one of the silicon germanium nanostructures and the high-k dielectric layer, wherein the interface layer comprises silicon oxide. In an embodiment, further including a dielectric structure disposed between the n-type region and the p-type region, wherein the dielectric structure electrically isolates the plurality of silicon nanostructures from the plurality of silicon germanium nanostructures.

In accordance with an embodiment, a method includes forming a plurality of silicon nanostructures above a semiconductor substrate in an n-type region of the semiconductor substrate, forming a plurality of silicon germanium nanostructures above the semiconductor substrate in a p-type region of the semiconductor substrate, wherein at least one of the plurality of silicon germanium nanostructures includes a silicon core region having a first concentration of germanium, wherein the first concentration of germanium is about 20% or less, a first silicon germanium region having a first interface between the silicon core region and the first silicon germanium region, and a second silicon germanium region having a second interface between the first silicon germanium region and the second silicon germanium region, the second silicon germanium region having a second concentration of germanium, wherein the second concentration of germanium is up to about 40%; wherein a first concentration gradient of germanium increases from the first concentration of germanium at the first interface to the second concentration of germanium at the second interface, depositing a high-k dielectric layer surrounding at least one of the plurality of silicon nanostructures and at least one of the plurality of silicon germanium nanostructures, and forming a gate electrode filling in a gap between adjacent ones of the plurality of silicon germanium nanostructures. In an embodiment, the at least one of the plurality of silicon germanium nanostructures further includes a third silicon germanium region having a third interface between the second silicon germanium region and the third silicon germanium region and an exterior surface opposite the third interface, wherein a second concentration gradient of germanium decreases from the second concentration of germanium at the third interface to about 0% germanium at the exterior surface. In an embodiment, the forming the plurality of silicon germanium nanostructures includes trimming a plurality of silicon nanostructures above the semiconductor substrate in the p-type region of the semiconductor substrate forming a plurality of trimmed silicon nanostructures, depositing silicon germanium over the plurality of trimmed silicon nanostructures, and performing an annealing process to diffuse germanium into the plurality of trimmed silicon nanostructures, wherein the annealing process forms the silicon core region, the first silicon germanium region, the second silicon germanium region, and the third silicon germanium region of at least one of the plurality of silicon germanium nanostructures. In an embodiment, the depositing silicon germanium is a chemical vapor deposition (CVD) performed in a CVD chamber at a first temperature. In an embodiment, the annealing process is performed in the CVD chamber at a second temperature greater than the first temperature. In an embodiment, further including forming a silicon cap layer surrounding at least one of the plurality of silicon germanium nanostructures. In an embodiment, further including forming an interface layer disposed between respective ones of the silicon germanium nanostructures and the high-k dielectric layer, wherein the interface layer comprises silicon oxide.

In accordance with an embodiment, a method includes forming a plurality of nanowires over semiconductor fins in both an n-type region and in a p-type region, forming a hard mask layer over a first set of the plurality of nanowires in the n-type region, performing a trimming process on a second set of the plurality of nanowires in the p-type region, depositing silicon germanium over each one nanowires of the second set of the plurality of nanowires, and performing an annealing process on the second set of the plurality of nanowires, wherein the annealing process diffuses germanium into at least one of the second set of the plurality of nanowires forming a plurality of silicon germanium nanostructures in the p-type region, wherein the plurality of silicon germanium nanostructures have different regions of varying germanium concentrations. In an embodiment, the depositing silicon germanium and the annealing process occur in a same chemical vapor deposition chamber. In an embodiment, the plurality of nanowires includes silicon and the annealing process diffuses up to about 20% concentration of germanium into a center of at least one of the second set of the plurality of nanowires. In an embodiment, the depositing silicon germanium is performed at a first temperature and the performing the annealing process occurs at a second temperature greater than the first temperature. In an embodiment, further including forming a silicon cap layer over at least one of the plurality of silicon germanium nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a substrate; and
a silicon germanium nanostructure over the substrate, the silicon germanium nanostructure having a first exterior surface and a second exterior surface opposite the first exterior surface, a germanium concentration profile between the first exterior surface and the second exterior surface being symmetric about a center of the silicon germanium nanostructure, the germanium concentration profile having a first maximum adjacent the first exterior surface and a second maximum adjacent the second exterior surface, a germanium concentration at the center being less than the first maximum and the second maximum;
a gate dielectric layer surrounding the silicon germanium nanostructure; and
a gate electrode surrounding the gate dielectric layer.

2. The device of claim 1, further comprising a silicon cap layer surrounding the silicon germanium nanostructure and disposed between the silicon germanium nanostructure and the gate dielectric layer.

3. The device of claim 1, wherein the germanium concentration decreases to about zero at the first exterior surface and at the second exterior surface.

4. The device of claim 1, wherein the germanium concentration profile comprises a first region adjacent the first exterior surface, the germanium concentration increasing across the first region from the first exterior surface to the first maximum.

5. The device of claim 4, wherein the germanium concentration profile further comprises a second region, the germanium concentration being constant across the second region at the first maximum.

6. The device of claim 5, wherein the germanium concentration profile further comprises a third region, the germanium concentration decreasing across the third region from the first maximum toward the center.

7. The device of claim 6, wherein the germanium concentration profile further comprises a fourth region at the center, the germanium concentration being constant across the fourth region.

8. The device of claim 1, wherein the center of the silicon germanium nanostructure is silicon.

9. A device comprising:
a silicon nanostructure over a substrate in an n-type region;
a silicon germanium nanostructure over the substrate in a p-type region, the silicon germanium nanostructure comprising a silicon core and silicon germanium surrounding the silicon core, the silicon core being narrower than the silicon nanostructure;
a gate dielectric layer around the silicon nanostructure and around the silicon germanium nanostructure; and
a gate electrode over the gate dielectric layer.

10. The device of claim 9, further comprising a silicon cap layer surrounding the silicon germanium nanostructure, the silicon cap layer being disposed between the silicon germanium and the gate dielectric layer.

11. The device of claim 9, further comprising first epitaxial source/drain regions on opposing sides of the silicon germanium nanostructure and second epitaxial source/drain regions on opposing sides of the silicon nanostructure.

12. The device of claim 11, wherein the first epitaxial source/drain regions on the opposing sides of the silicon germanium nanostructure exert a compressive strain on the silicon germanium nanostructure, and the second epitaxial source/drain regions on the opposing sides of the silicon nanostructure exert a tensile strain on the silicon nanostructure.

13. The device of claim 11, wherein the silicon germanium extends between the silicon core and the first epitaxial source/drain regions.

14. The device of claim 9, wherein a germanium concentration of the silicon germanium has a maximum at a location between the silicon core and an outer surface of the silicon germanium nanostructure, wherein the germanium concentration at an interface with the silicon core is less than the maximum, and the germanium concentration at the outer surface is less than the maximum.

15. A device comprising:
a channel structure over a substrate, the channel structure comprising:
a silicon core;
a silicon germanium layer surrounding the silicon core, the silicon germanium layer having a germanium concentration that increases with distance from the silicon core to a maximum and then decreases toward an outer surface of the silicon germanium layer; and
a silicon cap layer surrounding the silicon germanium layer;
a gate dielectric layer surrounding the silicon cap layer; and
a gate electrode surrounding the gate dielectric layer.

16. The device of claim 15, wherein the silicon core is free of germanium.

17. The device of claim 15, further comprising:
epitaxial source/drain regions on opposing sides of the channel structure, wherein the silicon germanium layer extends between the silicon core and the epitaxial source/drain regions.

18. The device of claim 15, wherein the germanium concentration is laterally symmetric about a center of the channel structure.

19. The device of claim 15, wherein the germanium concentration is vertically symmetric about a center of the channel structure.

20. The device of claim 15, wherein the silicon germanium layer comprises:
a first region adjacent the outer surface, the germanium concentration increasing across the first region from the outer surface toward the maximum;
a second region between the first region and the silicon core, the germanium concentration being constant across the second region at the maximum; and
a third region between the second region and the silicon core, the germanium concentration decreasing across the third region from the maximum toward the silicon core.
